(19) United States
(12) Patent Application Publication
(10) Pub. No.: US 2011/0254537 A1
(43) Pub. Date: Oct. 20, 2011

(54) Method and Apparatus for Detecting CCM Operation of a Magnetic Device

(75) Inventors: TA-YUNG YANG, MILPITAS, CA (US); JUNG-SHENG CHEN, KAOHSIUNG COUNTY (TW); LI LIN, TAIPEI (TW); PEI-SHENG TSU, TAIPEI COUNTY (TW); YI-MIN HSU, TAICHUNG CITY (TW); CHUH-CHING LI, TAOYUAN COUNTY (TW)

(73) Assignee: SYSTEM GENERAL CORP., TAIPEI HSIEN (TW)

(21) Appl. No.: 13/069,523

(22) Filed: Mar. 23, 2011

Related U.S. Application Data
(60) Provisional application No. 61/342,420, filed on Apr. 14, 2010.

(51) Int. Cl. G01R 19/00

(52) U.S. Cl. 324/76.11

(57) ABSTRACT

A method and an apparatus for detecting a CCM operation of a magnetic device are developed. The method generates a current signal in accordance with a switching current of the magnetic device and generates a first current signal and a second current signal by sampling the current signal. A mode signal is further generated according to the first current signal and the second current signal. The mode signal indicates the magnetic device is operated in CCM or DCM. The apparatus comprises a first sample circuit, a second sample circuit, and an arbiter. The first sample circuit samples the current signal to generate the first current signal. The second sample circuit samples the current signal to generate the second current signal. The arbiter generates the mode signal according to the first current signal and the second current signal for indicating the magnetic device is operated in CCM or DCM.

### REFERENCE TO RELATED APPLICATION

This application is based on Provisional Patent Application Ser. No. 61/342,420, filed 14 Apr. 2010, currently pending.

### FIELD OF THE INVENTION

The present invention relates to a method and an apparatus for detecting an operation mode of a magnetic device, more particularly, relates to a method and an apparatus for detecting a CCM/DCM operation of the magnetic device.

### BACKGROUND OF THE INVENTION

Power converters have been frequently used for converting an unregulated power source to a constant voltage source and/or a constant current source. To solve the problem of power loss, low on-resistance transistor has been used to replace the rectifying diode and to provide a synchronous rectification of power converter. It is important to enable the synchronous rectifier for improving its efficiency once a magnetic device is operated in CCM (continuous current mode). The system behavior is different when the magnetic device is running in DCM (discontinuous current mode) or CCM. Furthermore, the loop compensation in CCM/DCM should be different in order to make the loop stable. Thus, it would be helpful for power converters and PFC (power factor correction) circuits to achieve better performance if its CCM operation can be identified. The detail descriptions of CCM and DCM operation can be found in prior arts, such as “Method and apparatus for detecting switching current of magnetic device operated in continuous current mode” U.S. Pat. No. 7,518,416; and “Control circuit to reduce reverse current of synchronous rectifier” U.S. Pat. No. 7,570,038.

Please refer to FIG. 1, which shows a switching circuit including a magnetic device 10, a power transistor 20, a current sense device 30 and a control circuit 50. One terminal of the magnetic device 10 is coupled to receive an input voltage V_{IN}. The other terminal of the magnetic device 10 is coupled to a drain terminal of the power transistor 20. The current sense device 30 is coupled between a source terminal of the power transistor 20 and a ground. The control circuit 50 generates a switching signal V_{G} coupled to a gate terminal of the power transistor 20 to control the power transistor 20 for switching the magnetic device 10. A switching current I_{P} will be generated in response to the enabling of the switching signal V_{G}. That is, the switching current I_{P} is enabled by the switching signal V_{G}. The switching current I_{P} flowing across the current sense device 30 will generate a current signal V_{P} coupled to the control circuit 50. The current signal V_{P} is generated in accordance with the switching current I_{P} of the magnetic device 10. The control circuit 50 generates the switching signal V_{G} in response to a feedback signal V_{FB} and the current signal V_{P}.

### SUMMARY OF THE INVENTION

The primary purpose of the present invention relates to provide a method and apparatus for detecting an operation mode of a magnetic device. The magnetic device includes inductor, transformer and/or the winding of a motor, etc.

The still purpose of the present invention relates to provide a method and apparatus for detecting a CCM operation of a magnetic device. The magnetic device includes inductor, transformer and/or the winding of a motor, etc.

A method for detecting a CCM operation of a magnetic device is provided according to the present invention. It generates a current signal in accordance with a switching current of the magnetic device and generates a first current signal and a second current signal by sampling the current signal. The method further generates a mode signal according to the first current signal and the second current signal. The mode signal indicates the magnetic device is operated in CCM or DCM.

An apparatus for detecting a CCM operation of a magnetic device is provided according to the present invention. It comprises a first sample circuit, a second sample circuit, and an arbiter. The first sample circuit samples a current signal correlated to a switching current of the magnetic device to generate a first current signal. The second sample circuit samples the current signal to generate a second current signal. The arbiter generates a mode signal according to the first current signal and the second current signal for indicating the magnetic device is operated in CCM or DCM.

### BRIEF DESCRIPTION OF THE DRAWINGS

FIG. 1 shows the circuit schematic of a conventional switching circuit;

FIG. 2 shows the waveforms of the switching current and the switching signal;

FIG. 3 shows one of the preferred embodiments for the control circuit according to the present invention;

FIG. 4 shows the waveforms of the sample signals disclosed in the FIG. 3 according to the present invention;

FIG. 5 shows the circuit schematic of a preferred embodiment of the voltage-to-current converters disclosed in the FIG. 3 according to the present invention;

FIG. 6 shows the circuit schematic of a preferred embodiment of the arbiter circuit disclosed in the FIG. 3 according to the present invention;

FIG. 7 shows the circuit schematic of a preferred embodiment of the signal generator disclosed in the FIG. 3 according to the present invention; and

FIG. 8 shows the circuit schematic of a preferred embodiment of the PWM circuit disclosed in the FIG. 3 according to the present invention.

### DESCRIPTION OF THE EXEMPLARY EMBODIMENTS

Please refer to FIG. 2, which shows the waveforms of the switching current I_{P} and the switching signal V_{G}. The switching signal V_{G} and the switching current I_{P} are generated in response to the turn-on of the power transistor 20. The pulse width T_{W} represents an on-time of the switching signal V_{G}. The timing T_{B} shows the middle-point of the on-time of the switching signal V_{G}. The timing T_{C} shows the ending-point of the on-time of the switching signal V_{G}. If a threshold current I_{A} is existed in the switching current I_{P} when the switching signal V_{G} is started, it means the magnetic device 10 is operated under CCM. If the threshold current I_{A} equals to zero, it indicates the magnetic device 10 is operated under DCM. An average current I_{B} shows an average value of the switching current I_{P} during the on-time of the switching signal V_{G}. A peak current I_{C} shows a peak value of the switching current I_{P} during the on-time of the switching signal V_{G}. If two times of the average current I_{B} is higher than the peak current I_{C}, then the threshold current I_{A} must be higher than zero and the magnetic device 10 will be operated in CCM. On the other hands, if two times of the average current I_{B} is smaller than the peak current I_{C}, then the threshold current I_{A} must be equal to zero and the magnetic device 10 will be operated in DCM. The magnetic device 10 includes inductor, transformer and/or the winding of a motor, etc.

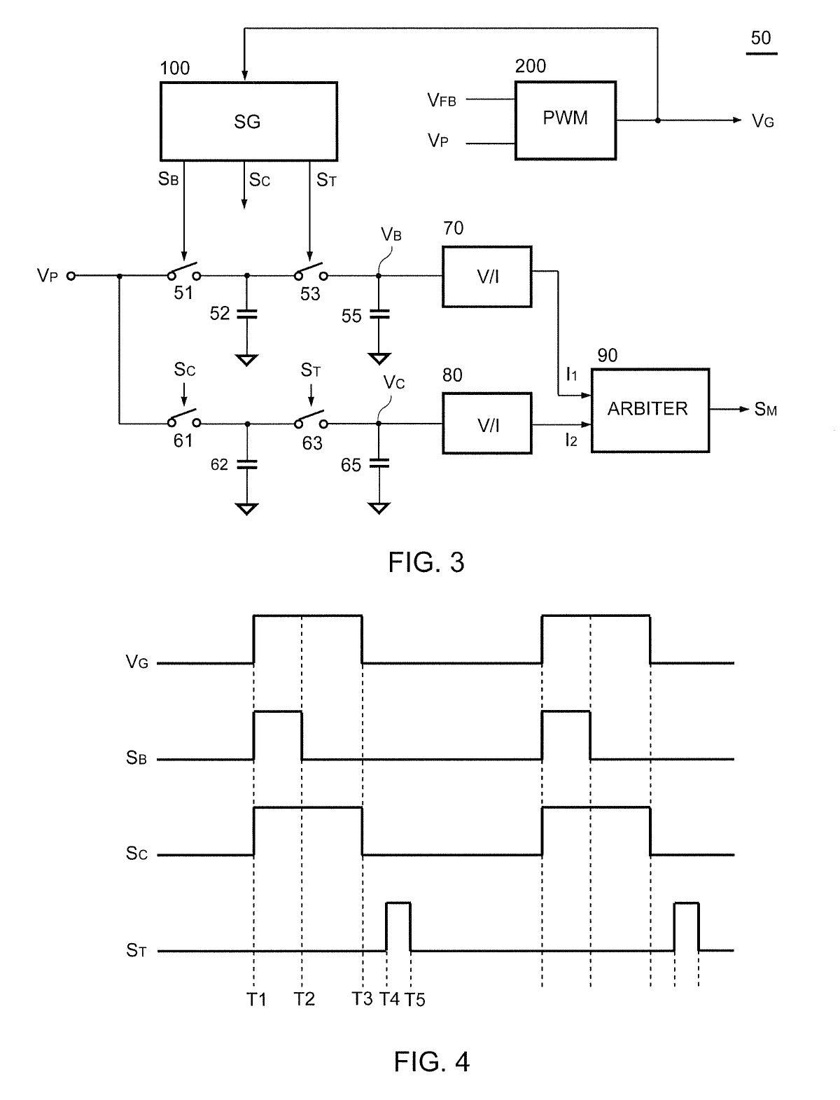

Referring to FIG. 3, which relates to a preferred embodiment of the control circuit 50 according to the present invention. The control circuit 50 includes a signal generator (SG) 100, a PWM circuit (PWM) 200, a first sample circuit, a second sample circuit, voltage-to-current converters (V/I) 70, 80 and an arbiter (ARBITER) 90. The PWM circuit 200 generates the switching signal V_{G} in response to the feedback signal V_{FB} and the current signal V_{P}. The signal generator (SG) 100, coupled to the PWM circuit 200, generates a first sample signal S_{B}, a second sample signal S_{C} and a sample signal S_{T} in response to the switching signal V_{G}. The first sample circuit includes switches 51, 53 and capacitors 52, 55. The switch 51 controlled by the first sample signal S_{B} is coupled to the capacitor 52 in accordance with the current signal V_{P}. The capacitor 52 is coupled between the switch 51 and the ground. The switch 53 controlled by the sample signal S_{T} is coupled to the capacitor 55 in accordance with a signal at the capacitor 52. The capacitor 55 is coupled between the switch 53 and the ground. A first current signal V_{B} is generated at the capacitor 55. In brief, the first sample circuit coupled to the signal generator 100 receives the first sample signal S_{B} and the sample signal S_{T}. Furthermore, the first sample circuit samples the current signal V_{P} and generates the first current signal V_{B} in accordance with the first sample signal S_{B} and the sample signal S_{T}.

The second sample circuit includes switches 61, 63 and capacitors 62, 65. The switch 61 controlled by the second sample signal S_{C} is coupled to the capacitor 62 in accordance with the current signal V_{P}. The capacitor 62 is coupled between the switch 61 and the ground. The switch 63 controlled by the sample signal S_{T} is coupled to the capacitor 65 in accordance with a signal at the capacitor 62. The capacitor 65 is coupled between the switch 63 and the ground. A second current signal V_{C} is generated at the capacitor 65. In brief, the second sample circuit coupled to the signal generator 100 receives the second sample signal S_{C} and the sample signal S_{T}. Furthermore, the second sample circuit samples the current signal V_{P} and generates the second current signal V_{C} in accordance with the second sample signal S_{C} and the sample signal S_{T}. As just mentioned, the first sample signal S_{B} and the second sample signal S_{C} are coupled to generate the first current signal V_{B} and the second current signal V_{C} respectively. The first sample circuit and the second sample circuit generate the first current signal V_{B} and the second current signal V_{C} by sampling the current signal V_{P}.

The voltage-to-current converter 70 coupled to the first sample circuit receives the first current signal V_{B} to generate an average current I₁. The voltage-to-current converter 80 coupled to the second sample circuit receives the second current signal V_{C} to generate a peak current I₂. Through voltage-to-current converters 70 and 80, the first current signal V_{B} and the second current signal V_{C} are converted to the average current I₁ and the peak current b. The outputs of the average current and the peak current I₂ are coupled to the arbiter circuit 90 to generate a mode signal S_{M}. In this manner, the first current signal V_{B} is correlated to an average value of the current signal V_{P} during the on-time of the switching signal V_{G}. The second current signal V_{C} is correlated to a peak value of the current signal V_{P} during the on-time of the switching signal V_{G}. The current signal V_{P} is correlated to the switching current I_{P} (as shown in FIG. 2). Therefore, the first current signal V_{B} is correlated to the average value of the switching current I_{P} during the on-time of the switching signal V_{G}, and the second current signal V_{C} is correlated to the peak value of the switching current I_{P} during the on-time of the switching signal V_{G}. The mode signal S_{M} is generated in response to the first current signal V_{B} and the second current signal V_{C}. The mode signal S_{M} indicates that the magnetic device is operated in CCM or DCM.

Referring to FIG. 4, which shows the waveforms of the sample signals S_{B}, S_{C} and S_{T} and the switching signal V_{G} according the present invention. The first sample signal S_{B} and the second sample signal S_{C} are generated in response to an enabling of the switching signal V_{G}. Furthermore, the first sample signal S_{B} is generated during the on-time of the switching signal V_{G}. The second sample signal S_{C} and the switching signal V_{G} are in phase and their pulse widths are all the same duration. The sample signal S_{T} is generated after the on-time of the switching signal V_{G}. Meanwhile, the sample signals S_{B}, S_{C} and the switching signal V_{G} have aligned rising edges at the timing T₁. The second sample signal S_{C} and the switching signal V_{G} have aligned falling edges at the timing T₃. Between the timing T₁ and the timing T₃, the first sample signal S_{B} has a falling edge at the timing T₂.

The pulse width of the second sample signal S_{C} is longer than the pulse width of the first sample signal S_{B}. Because the first sample signal S_{B} is ended at the middle of the on-time (the timing T₂) of the switching signal V_{G}, and the second sample signal S_{C} is ended at the end of the on-time of the switching signal V_{G} (the timing T₃). Thus, the first current signal V_{B} (as shown in FIG. 3) is sampled at the middle of the on-time of the switching signal V_{G}, and the second current signal V_{C} (as shown in FIG. 3) is sampled at the end of the on-time of the switching signal V_{G}. The signals stored in the capacitors 52 and 62 are transferred to the capacitors 55 and 65 respectively by the sample signal S_{T}. Between the timing T₄ and the timing T₅, the sample signal S_{T} is generated after the end of the second sample signal S_{C}.

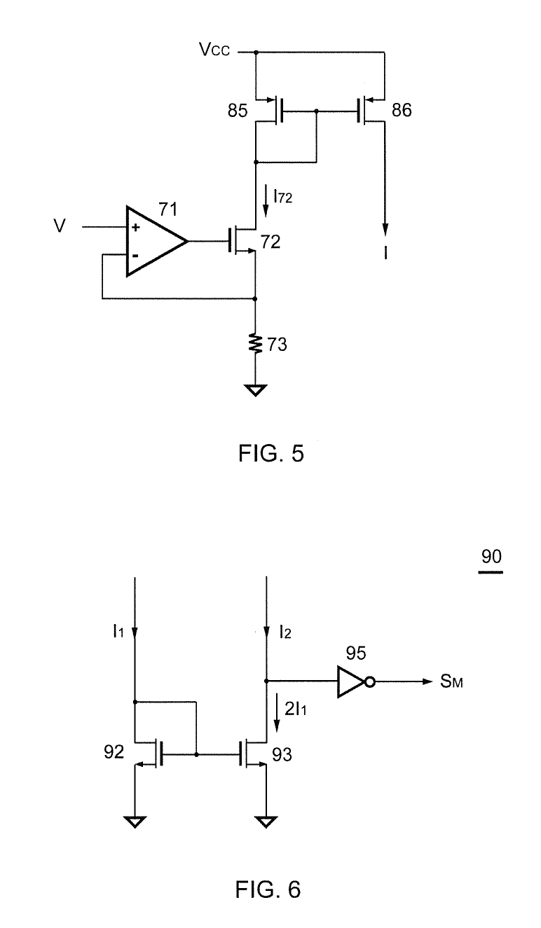

Please refer to FIG. 5, which shows the circuit schematic of the voltage-to-current converters 70 and 80. Each of the voltage-to-current converters 70 and 80 includes an operational amplifier 71, a transistor 72, a resistor 73 and a current mirror formed by transistors 85 and 86. The operational amplifier 71 receives an input signal V at its positive input terminal. The input signal V is the first current signal V_{B} or the second current signal V_{C} (as shown in FIG. 3). A negative input terminal of the operational amplifier 71 is coupled to a source terminal of the transistor 72. A gate terminal of the transistor 72 is coupled to an output terminal of the operational amplifier 71. The resistor 73 is coupled between the negative input terminal of the operational amplifier 71 and the ground.

A current I₇₂ is generated at a drain terminal of the transistor 72 through the input signal V being divided by the resistor 73. A drain terminal of the transistor 85 receives the current I₇₂. Gate terminals of the transistor 85 and the transistor 86 are coupled each other and they all are coupled to the drain terminals of the transistor 85 and the transistor 72. Source terminals of transistor 85 and the transistor 86 are coupled to a supply voltage V_{CC}. An output signal I is generated at a drain terminal of the transistor 86 in response to the current I₇₂. The output signal I is the average current I₁ or the peak current I₂ (as shown in FIG. 3). In other words, the drain terminal of the transistor 85 receives the current I₇₂ and mirrors to the drain terminal of the transistor 86 through the current mirror. Therefore, the current mirror receives the current I₇₂ to generate the output signal I. The voltage-to-current converter receives the input signal V to generate the output signal I.

Referring to FIG. 6, which relates to a preferred embodiment of the arbiter circuit 90. The arbiter circuit 90 includes an inverter 95 and a current mirror developed by transistors 92 and 93. A drain terminal of the transistor 92 receives the average current I₁. Gate terminals of the transistor 92 and the transistor 93 are coupled each other and they all are coupled to the drain terminal of the transistor 92. Source terminals of the transistor 92 and the transistor 93 are coupled to the ground. However, the geometric size of the transistor 93 is two times of the geometric size of the transistor 92. A drain terminal of the transistor 93 generates a current 2I₁ that is two times of the average current I₁ through the current mirror.

The inverter 95 is coupled to the drain terminal of the transistor 93 and the peak current I₂. Through the inverter 95, the mode signal S_{M} is generated by comparing the peak current I₂ with the current 2I₁ that is two times of the average current I₁. The mode signal S_{M} will be enabled (logic high) if two times of the average current I₁ is higher than the peak current b. Therefore, the mode signal S_{M} is enabled if two times of the first current signal V_{B} is higher than the second current signal V_{C} (as shown in FIG. 3). In the meantime, the mode signal S_{M} indicates that the magnetic device is operated in CCM. On the other hands, the mode signal S_{M} is disabled if two times of the first current signal V_{B} is lower than the second current signal V_{C}, and the magnetic device is operated in DCM.

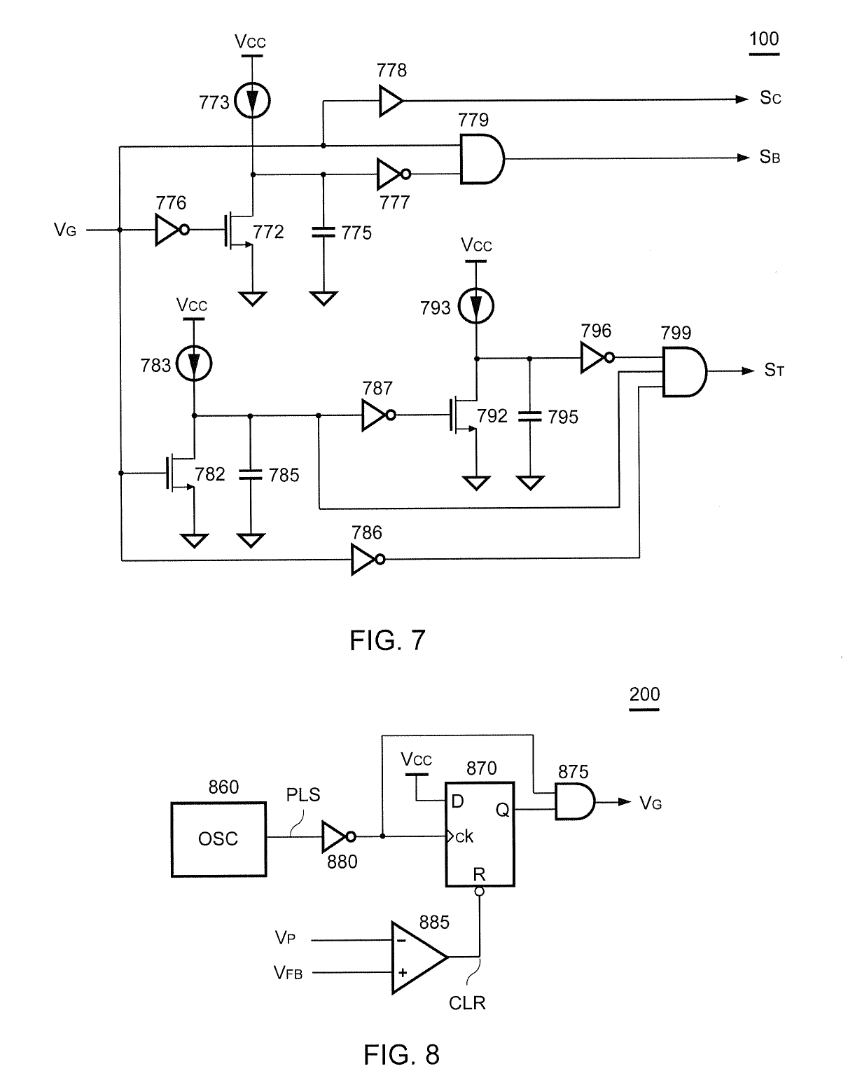

FIG. 7 shows a preferred embodiment of the signal generator 100 in accordance with the present invention. A gate terminal of a transistor 772 receives the switching signal V_{G} through an inverter 776. The switching signal V_{G} is coupled to control the transistor 772 through the inverter 776. A current source 773 is coupled between the supply voltage V_{CC} and a drain terminal of the transistor 772. A source terminal of the transistor 772 is coupled to the ground. A capacitor 775 is connected between the drain terminal of the transistor 772 and the ground. The transistor 772 is coupled to the capacitor 775 in parallel to discharge the capacitor 775 once the transistor 772 is turned on. The current source 773 is connected to the supply voltage V_{CC} and is used to charge the capacitor 775 once the transistor 772 is turned off. Thus, the current source 773 and the capacitance of the capacitor 775 determine the pulse-width (between the timing T₁ and the timing T₂ shown in FIG. 4) of the voltage across the capacitor 775.

The switching signal V_{G} is further transmitted to an input of an AND gate 779. Another input of the AND gate 779 is coupled to the capacitor 775 and the drain terminal of the transistor 772 via an inverter 777. Hence, the first sample signal S_{B} is generated at an output terminal of the AND gate 779 and the pulse-width (between the timing T₁ and the timing T₂) of the first sample signal S_{B} is determined by the current source 773 and the capacitance of the capacitor 775. The second sample signal S_{C} is generated in response to the switching signal V_{G} through a buffer 778 coupled to the switching signal V_{G}. The pulse-width (between the timing T₁ and the timing T₃ shown in FIG. 4) of the second sample signal S_{C} is correlated to the switching signal V_{G}.

The switching signal V_{G} is coupled to control a transistor 782 through a gate terminal of the transistor 782. A current source 783 is coupled between the supply voltage V_{CC} and a drain terminal of the transistor 782. A source terminal of the transistor 782 is coupled to the ground. A capacitor 785 is connected between the drain terminal of the transistor 782 and the ground. The transistor 782 is coupled to the capacitor 785 in parallel to discharge the capacitor 785 once the transistor 782 is turned on. The current source 783 is connected to the supply voltage V_{C}c and is used to charge the capacitor 785 once the transistor 782 is turned off. Thus, the current source 783 and the capacitance of the capacitor 785 determine the pulse-width (between the timing T₃ and the timing T₄ shown in FIG. 4) of the voltage across the capacitor 785.

A gate terminal of a transistor 792 is coupled to the capacitor 785 and the drain terminal of the transistor 782 via an inverter 787. A current source 793 is coupled between the supply voltage V_{CC} and a drain terminal of the transistor 792. A source terminal of the transistor 792 is coupled to the ground. A capacitor 795 is connected between the drain terminal of the transistor 792 and the ground. The transistor 792 is coupled to the capacitor 795 in parallel to discharge the capacitor 795 once the transistor 792 is turned on. The current source 793 is connected to the supply voltage V_{CC} and is used to charge the capacitor 795 once the transistor 792 is turned off. Thus, the current source 793 and the capacitance of the capacitor 795 determine the pulse-width (between the timing T₄ and the timing T₅ shown in FIG. 4) of the voltage across the capacitor 795.

As shown in FIG. 7, a first input terminal of an AND gate 799 is coupled to the capacitor 795 and the drain terminal of the transistor 792 via an inverter 796. A second input terminal of the AND gate 799 is coupled to the capacitor 785 and the drain terminal of the transistor 782. A third input terminal of the AND gate 799 receives the switching signal V_{G} through an inverter 786. Hence, the sample signal S_{T} is generated at an output terminal of the AND gate 799 and the pulse-width (between the timing T₄ and the timing T₅) of the sample signal S_{T} is determined by the current source 793 and the capacitance of the capacitor 795.

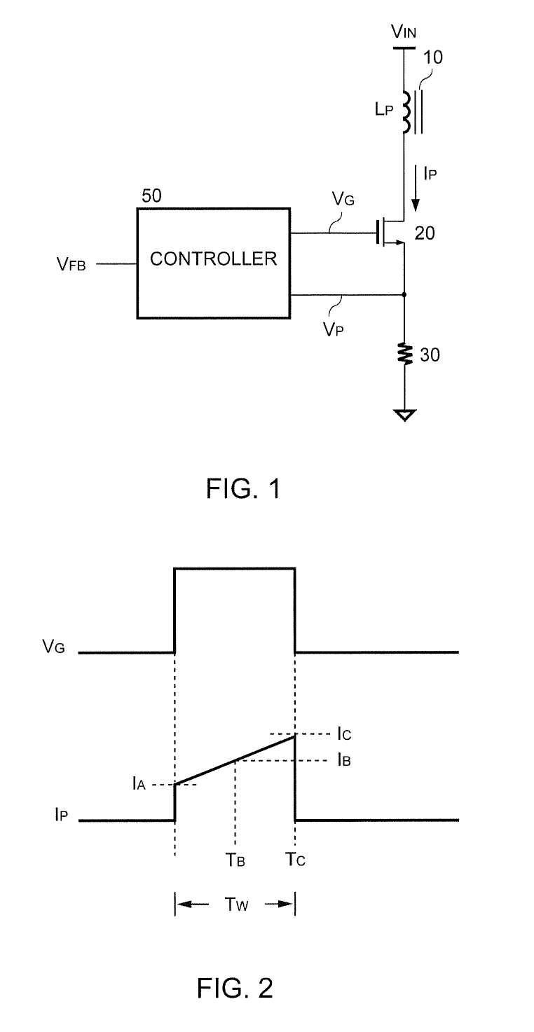

FIG. 8 shows the circuit schematic of a preferred embodiment of the PWM circuit 200 in accordance with the present invention. The PWM circuit 200 comprises an oscillator (OSC) 860, an inverter 880, a D-type Flip-Flop 870, an AND gate 875 and a comparator 885. The oscillator 860 generates a pulse signal PLS. A clock input of the D-type Flip-Flop 870 receives the pulse signal PLS via the inverter 880. The inverter 880 is coupled between the oscillator 860 and the clock input of the D-type Flip-Flop 870. The supply voltage V_{CC} is supplied with a D input of the D-type Flip-Flop 870. The feedback signal V_{FB} from the output of the power converter is supplied with a positive input of the comparator 885. A negative input of the comparator 885 connects to the current sense device 30 (as shown in FIG. 1) to receive the current signal V_{P}. A reset input R of the D-type Flip-Flop 870 is coupled to an output of the comparator 885 to receive a clear signal CLR. A first input terminal of the AND gate 875 is coupled to an output of the inverter 880. A second input terminal of the AND gate 875 is coupled to an output Q of the D-type Flip-Flop 870. An output of the AND gate 875 generates the switching signal V_{G} to switch the power transistor 20 (as shown in FIG I) in response to the pulse signal PLS and the clear signal CLR. The comparator 885 generates the clear signal CLR to periodically disable the switching signal V_{G} when the current signal V_{P} is higher than the feedback signal V_{FB}. Therefore, the output of the power converter is regulated.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for detecting a CCM operation of a magnetic device, comprising:
generating a current signal in accordance with a switching current of the magnetic device;
generating a first current signal and a second current signal by sampling the current signal; and
generating a mode signal according to the first current signal and the second current signal;
wherein the switching current is enabled by a switching signal; the first current signal is correlated to an average value of the switching current during the on-time of the switching signal; the second current signal is correlated to a peak value of the switching current during the on-time of the switching signal; the mode signal indicates the magnetic device is operated in CCM or DCM.

2. The method as claimed in claim 1, wherein a first sample signal and a second sample signal are generated in response to an enabling of the switching signal, the first sample signal and the second sample signal are coupled to generate the first current signal and the second current signal respectively, and a pulse width of the second sample signal is longer than a pulse width of the first sample signal.

3. The method as claimed in claim 1, wherein the first current signal is sampled at the middle of the on-time of the switching signal; and the second current signal is sampled at the end of the on-time of the switching signal.

4. The method as claimed in claim 1, wherein the mode signal is enabled if two times the value of the first current signal is higher than the value of the second current signal.

5. A method for detecting a CCM operation of a magnetic device, comprising:
generating a current signal in accordance with a switching current of the magnetic device;
generating a first current signal and a second current signal by sampling the current signal; and
generating a mode signal according to the first current signal and the second current signal;
wherein the switching current is enabled by a switching signal; the first current signal is sampled at the middle of the on-time of the switching signal; and the second current signal is sampled at the end of the on-time of the switching signal; the mode signal indicates the magnetic device is operated in CCM or DCM.

6. The method as claimed in claim 5, wherein a first sample signal and a second sample signal are generated in response to an enabling of the switching signal, the first sample signal and the second sample signal are coupled to generate the first current signal and the second current signal respectively, and a pulse width of the second sample signal is longer than a pulse width of the first sample signal.

7. The method as claimed in claim 5, wherein the mode signal is enabled if two times the value of the first current signal is higher than the value of the second current signal.

8. An apparatus for detecting a CCM operation of a magnetic device, comprising:
a first sample circuit sampling a current signal correlated to a switching current of the magnetic device to generate a first current signal;
a second sample circuit sampling the current signal to generate a second current signal; and
an arbiter generates a mode signal according to the first current signal and the second current signal, the mode signal indicating the magnetic device is operated in CCM or DCM.

9. The apparatus as claimed in claim 8, wherein the switching current is enabled by a switching signal, the first current signal is correlated to an average value of the switching current during the on-time of the switching signal, the second current signal is correlated to a peak value of the switching current during the on-time of the switching signal.

10. The apparatus as claimed in claim 9, further comprising a PWM circuit generating the switching signal for switching the magnetic device.

11. The apparatus as claimed in claim 8, wherein the first current signal is sampled at the middle of the on-time of a switching signal, and the second current signal is sampled at the end of the on-time of the switching signal.

12. The apparatus as claimed in claim 8, wherein the arbiter enables the mode signal if two times the value of the first current signal is higher than the value of the second current signal.

13. The apparatus as claimed in claim 8, further comprising a signal generator generating a first sample signal and a second sample signal in response to an enabling of a switching signal, the first sample signal and the second sample signal coupled to generate the first current signal and the second current signal respectively, and a pulse width of the second sample signal being longer than a pulse width of the first sample signal.

14. The apparatus as claimed in claim 8, further comprising a current sense device generating the current signal in accordance with the switching current of the magnetic device.

15. The apparatus as claimed in claim 8, further comprising voltage-to-current converters converting the first current signal and the second current signal to an average current and a peak current, the arbiter generating the mode signal according to the average current and the peak current.
